(19) United States
(12) Patent Application Publication
(10) Pub. No.: US 2015/0091146 A1
(43) Pub. Date: Apr. 2, 2015

(54) POWER SEMICONDUCTOR PACKAGE

(71) Applicant: SAMSUNG ELECTRO-MECHANICS CO., LTD., Suwon-Si (KR)

(72) Inventors: Kyu Hwan Oh, Suwon-Si (KR); Si Joong Yang, Suwon-Si (KR); Do Jae Yoo, Suwon-Si (KR); Young Hoon Kwak, Suwon-Si (KR)

(73) Assignee: SAMSUNG ELECTRO-MECHANICS CO., LTD., Suwon-Si (KR)

(21) Appl. No.: 14/288,210

(22) Filed: May 27, 2014

(30) Foreign Application Priority Data
Sep. 27, 2013 (KR) 10-2013-0115583

(51) Int. Cl. H01L 23/495; H01L 23/31

(52) U.S. Cl. CPC H01L 23/49568; H01L 23/49575; H01L 23/49562; H01L 23/3114
USPC 257/675

(57) ABSTRACT

Disclosed herein is a power semiconductor package. The power semiconductor package according to a preferred embodiment of the present invention includes: a semiconductor device; a circuit pattern formed on the semiconductor device; a molding member burying the semiconductor device and the circuit pattern and formed so as to expose one surface of the circuit pattern; and a heat radiating member adhered to the circuit pattern exposed by the molding member and formed of a non-conductive material.

### CROSS REFERENCE TO RELATED APPLICATION

This application claims the benefit of Korean Patent Application No. 10-2013-0115583, filed on Sep. 27, 2013, entitled “Power Semiconductor Package”, which is hereby incorporated by reference in its entirety into this application.

### BACKGROUND OF THE INVENTION

1. Technical Field

The present invention relates to a power semiconductor package.

2. Description of the Related Art

In accordance with an increase in energy consumption around the world, an interest in efficient use of restricted energy has significantly increased.

In accordance with an increase in use of a power package, the market's demand for a power module having a multi-function and a small size has increased. Therefore, a heat generation problem of an electronic component has caused deterioration of performance of the entire module.

Therefore, in order to increase efficiency of the power package and secure high reliability thereof, a structure capable of solving the above-mentioned heat generation problem has been required. In order to solve the above-mentioned heat generation problem, a cooling unit for cooling the power package may be installed on one surface of the power package (U.S. Pat. No. 6,344,686).

### SUMMARY OF THE INVENTION

The present invention has been made in an effort to provide a power semiconductor package capable of improving heat radiating performance

According to a preferred embodiment of the present invention, there is provided a power semiconductor package, including: a semiconductor device; a circuit pattern formed on the semiconductor device; a molding member burying the semiconductor device and the circuit pattern and formed so as to expose one surface of the circuit pattern; and a heat radiating member adhered to the circuit pattern exposed by the molding member and formed of a non-conductive material.

The power semiconductor package may further include an attaching member formed between the semiconductor device and the circuit pattern to thereby attach to each other.

The attaching member may be formed of a solder.

The circuit pattern may be formed of a conductive material.

The circuit pattern may be formed of copper.

The power semiconductor package may further include a lead frame having one end adhered to the circuit pattern and the other end protruded to the outside of the molding member.

The lead frame may be formed of a conductive material.

The lead frame may be formed of copper.

The circuit pattern may be formed so as to have a structure in which a portion of a side thereof is convexly protruded.

The circuit pattern may be formed so as to have a structure in which a portion of a side thereof is concavely depressed.

The circuit pattern may be formed so as to have a hook structure which is upwardly protruded, on a side thereof.

A plurality of semiconductor devices may be formed.

The semiconductor device may include at least one of a power device and a control device.

The circuit pattern may be formed on each of the plurality of semiconductor devices.

The heat radiating member may be simultaneously adhered to the plurality of circuit patterns.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an illustrative view showing a power semiconductor package according to a preferred embodiment of the present invention;

FIG. 2 is an illustrative view showing a circuit pattern and a molding member according to a preferred embodiment of the present invention;

FIG. 3 is an illustrative view showing a structure of the circuit pattern according to a preferred embodiment of the present invention;

FIG. 4 is an illustrative view showing another structure of the circuit pattern according to a preferred embodiment of the present invention;

FIG. 5 is an illustrative view showing still another structure of the circuit pattern according to a preferred embodiment of the present invention; and

FIG. 6 is an illustrative view for a power semiconductor package according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

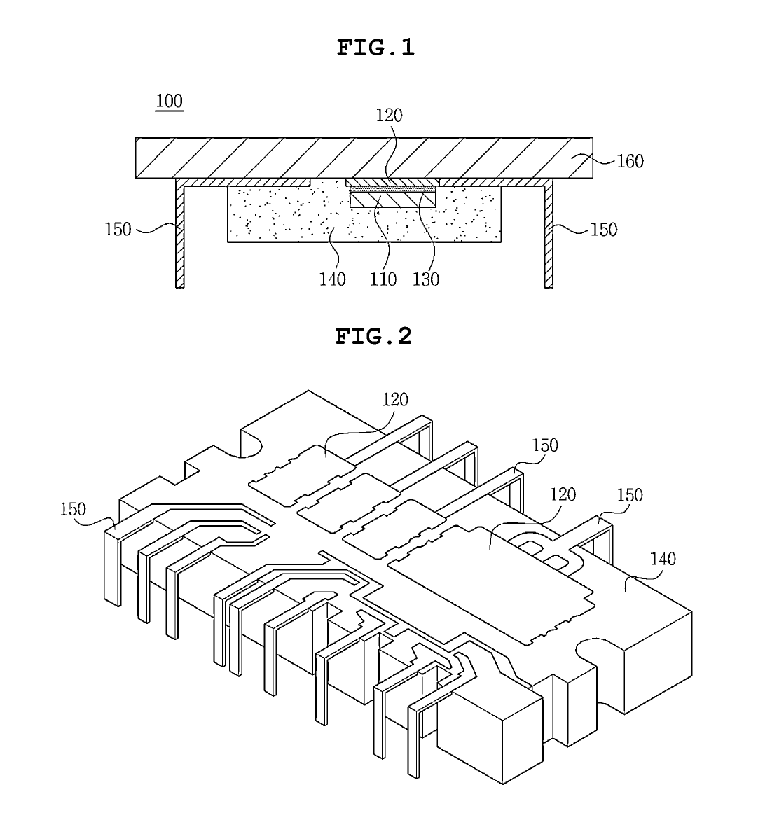

FIG. 1 is an illustrative view showing a power semiconductor package according to a preferred embodiment of the present invention.

Referring to FIG. 1, a power semiconductor package 100 may include the semiconductor device 110, a circuit pattern 120, an attaching member 130, a molding member 140, a lead frame 150, and a heat radiating member 160.

The semiconductor device 110 may include at least one of a power device and a control device. In the preferred embodiment of the present invention, the semiconductor device 110 may be formed by only at least one power device. Alternatively, the semiconductor device 110 may be formed by at least one group including the power device and the control device.

For example, the power device may include an insulated gate bipolar transistor (IGBT), a diode, or the like. In addition, the control device may include a control integrated circuit (IC), or the like.

The circuit pattern 120 may be formed on one surface of the semiconductor device 110. The circuit pattern 120 may serve to transfer an electrical signal. In this case, the circuit pattern 120 may be electrically connected to the semiconductor device 110. Alternatively, the circuit pattern 120 may separately serve to transfer the electrical signal even though it is not electrically connected to the semiconductor device 110. In addition, the circuit pattern 120 may transfer heat generated from the semiconductor device 110 to the heat radiating member 160. In the preferred embodiment of the present invention, the circuit pattern 120 may be formed of a conductive material. For example, the conductive material may be copper. However, the material of the circuit pattern 120 is not limited to copper, and any conductive material used in a field of a circuit substrate may be used.

In the case in which a plurality of semiconductor devices 110 are formed, a plurality of circuit patterns 120 may also be formed, as needed. Therefore, the circuit pattern 120 may be formed on each of the semiconductor devices 110.

In addition, the circuit pattern 120 may have one surface which is formed so as to be exposed from the molding member 140, as shown. The above-mentioned structure will be described in detail with reference to FIG. 2.

In addition, in the preferred embodiment of the present invention, a side of the circuit pattern 120 may be patterned. For example, the side of the circuit pattern 120 may be formed so that a portion thereof has a bent concave structure. Alternatively, the side of the circuit pattern 120 may be formed so that the portion thereof has a structure protruded from the side. Alternatively, the side of the circuit pattern 120 may be formed so as to have a hook structure which is upwardly protruded. The structure of the circuit pattern 120 as described above may increase an attached area between the circuit pattern 120 and the molding member 140 to thereby improve adhesion therebetween.

The attaching member 130 may be formed between the circuit pattern 120 and the semiconductor device 110. The attaching member 130 may improve adhesion between the circuit pattern 120 and the semiconductor device 110. For example, the attaching member 130 may be formed of a solder. However, a material of the attaching member 130 is not limited to the solder. As the material of the attaching member 130, any material used in the field of the circuit substrate and capable of improving adhesion may be used.

The molding member 140 may be formed so as to surround the semiconductor device 110 and the circuit pattern 120. The molding member 140 may be formed so as to prevent the semiconductor device 110 and the circuit pattern 120 from being damaged from an external environment. In this case, the molding member 140 may expose one surface of the circuit pattern 120. That is, one surface of the molding member 140 and one surface of the circuit pattern 120 may be collinearly disposed. For example, the molding part 140 may be formed of an epoxy molding compound (EMC).

The lead frame 150 may be formed so as to electrically connect the power semiconductor package 100 to the outside. The lead frame 150 may have one end connected to the circuit pattern 120. In addition, the lead frame 150 may have the other end formed so as to be protruded to the outside of the molding member 140. In this case, one surface of the lead frame 150 may be formed so as to be exposed from the molding member 140 similar to the circuit pattern 120. In the preferred embodiment of the present invention, the lead frame 150 and the circuit pattern 120 have been described as a separate configuration part. However, even though the lead frame 150 and the circuit pattern 120 may be separately formed to be adhered to each other, they may also be integrally formed.

The heat radiating member 160 may be formed on the circuit pattern 120. The heat radiating member 160 may be directly adhered to the circuit pattern 120 exposed from the molding member 140. According to the prior art, an insulation layer for insulation was formed between the circuit pattern and the heat radiating member. Therefore, according to the prior art, the heat generated from the semiconductor device was transferred to the heat radiating member through the circuit pattern and the insulation layer. In this case, thermal resistance is increased by the circuit pattern and the insulation layer between the semiconductor device and the heat radiating member and heat conductivity is also decreased, thereby decreasing heat radiating effect. However, since the preferred embodiment of the present invention forms a structure in which the heat radiating member 160 is directly adhered to the circuit pattern 120, the heat generated from the semiconductor device 110 may be transferred to the heat radiating member 160 only through the circuit pattern 120. Therefore, the structure in which the circuit pattern 120 and the heat radiating member 160 are directly adhered to each other according to the preferred embodiment of the present invention may decrease the thermal resistance to thereby improve the heat radiating effect.

In this case, the heat radiating member 160 according to the preferred embodiment of the present invention may be formed of a non-conductive material. Thereby, insulation between the plurality of circuit patterns 120 and insulation between the circuit pattern 120 and the heat radiating member 160 may be implemented.

FIG. 2 is an illustrative view showing a circuit pattern and a molding member according to a preferred embodiment of the present invention.

As shown in FIG. 2, the circuit pattern 120 may have one surface formed so as to be exposed from the molding member 140. In addition, the circuit pattern 120 may have the other surface buried in the molding member 140. The semiconductor device (110 of FIG. 1) disposed on the other surface of the circuit pattern 120 may also be buried in the molding member 140.

In addition, the lead frame 150 may have one end which is also formed so as to be buried in the molding member 140. Herein, one end of the lead frame 150 may be adhered to the circuit pattern 120 or may be adhered to other configuration parts in the molding member 140. One end of the lead frame 150 may also have one end exposed from the molding member 140 and the other end buried in the molding member 140.

As described above, one surface of the circuit pattern 120 is formed so as to be exposed to one surface of the molding member 140, such that the heat radiating member (160 of FIG. 1) may directly contact the circuit pattern 120. Therefore, the heat generated from the semiconductor device (110 of FIG. 1) is conducted to the heat radiating member (160 of FIG. 1) by passing through only the circuit pattern 120, thereby making it possible to improve the heat radiating effect.

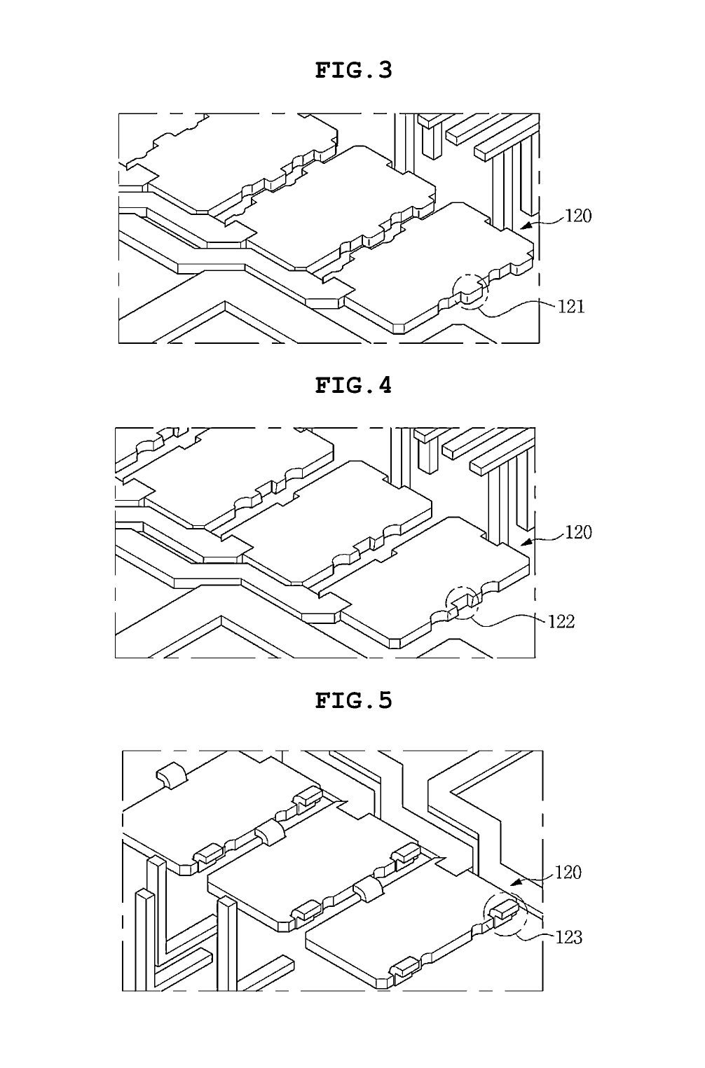

FIG. 3 is an illustrative view showing a structure of the circuit pattern according to a preferred embodiment of the present invention.

Referring to FIG. 3, the circuit pattern 120 may have a protrusion part 121 formed on a side thereof. The protrusion part 121 may be formed so that a portion of the side of the circuit pattern 120 is convexly protruded.

When the molding member 140 is formed on the circuit pattern 120, an adhering area between the molding member 140 and the circuit pattern 120 is increased by the protrusion part 121 of the circuit pattern 120. In accordance with the increase in the adhering area as described above, adhesion between the circuit pattern 120 and the molding member 140 may be increased and reliability of the power semiconductor package (100 of FIG. 1) may be improved.

The following Table 1 shows variations in thermal resistance of a power semiconductor package according to the prior art and the power semiconductor package according to the preferred embodiment of the present invention.

The power semiconductor package according to the prior art has a structure in which an insulation layer and a metal layer are formed on one surface of the circuit pattern. The power semiconductor package 100 according to the preferred embodiment of the present invention has a structure in which the circuit pattern 120 is formed so as to be exposed to the molding member 140. In this case, the semiconductor device has a size of 11×11 mm².

TABLE 1

| | K | L | Prior | Preferred embodiment of |
|---|---|---|---|---|
| Material | (W/mk) | (mm) | art | the present invention |
| Attaching member | 40 | 0.08 | 0.017 | 0.017 |
| Circuit pattern | 350 | 0.3 | 0.007 | 0.007 |
| Insulation layer | 5 | 0.08 | 0.132 | — |
| Metal layer | 140 | 2 | 0.118 | — |

| | | |
|---|---|---|
| Total thermal resistance | 0.274 | 0.024 |

In addition, the thermal resistance may be represented by the following Equation 1.

Thermal resistance=Length(L)/[Heat conductivity(K)×Area(A)] [Equation 1]

As may be seen in Table 1, it may be appreciated that the preferred embodiment of the present invention has the thermal resistance lower as compared to that of the prior art. Since the prior art includes the insulation layer and the metal layer, the prior art shows a value of thermal resistance higher by about 12 times as compared to that of the preferred embodiment of the present invention.

Converting this result into a junction temperature, the junction temperature may be represented by the following Table 2.

TABLE 2

| | Prior | Preferred embodiment of |
|---|---|---|
| Items | art | the present invention |
| Case Temp. (° C.) | 45 | 45 |
| Power loss (W) | 50 | 50 |
| Thermal resistance (° C./W) | 0.274 | 0.024 |
| Junction Temp. (° C.) | 58.7 | 46.2 |

As may be seen in Table 2, it may be appreciated that the junction temperature according to the prior art is higher by 27% as compared to that of the preferred embodiment of the present invention. That is, the power semiconductor package 100 according to the preferred embodiment of the present invention may omit the insulation layer and the metal layer according to the prior art between the circuit pattern 120 and the heat radiating member 160, thereby making it possible to decrease the heat. Therefore, the junction temperature of the semiconductor device 110 may be decreased, such that heat radiating performance of the power semiconductor package 100 may be improved.

FIG. 4 is an illustrative view showing another structure of the circuit pattern according to a preferred embodiment of the present invention.

Referring to FIG. 4, the circuit pattern 120 may have a depression part 122 formed on a side thereof. The depression part 122 may be formed so that a portion of the side of the circuit pattern 120 is concavely depressed.

When the molding member 140 is formed on the circuit pattern 120, the depression part 122 of the circuit pattern 120 is filled with the molding member 140. Therefore, an adhering area between the circuit pattern 120 and the molding member 140 is increased by the depression part 122 of the circuit pattern 120.

One surface of the depression part 122, which is one surface of the circuit pattern 120, is a portion exposed from the molding member 140. The other surface of the depression part 122, which is the other surface of the circuit pattern 120, is a portion buried in the molding member 140.

In the preferred embodiment of the present invention, the depression part 122 of the circuit pattern 120 may be formed so as to have an inclined surface. As shown in FIG. 4, the depression part 122 may approach a side line of the circuit pattern 120 toward the other surface thereof from one surface thereof. Therefore, the depression part 122 may be filled with more of the molding member 140 toward one surface thereof from the other surface thereof. Therefore, it is possible to prevent the circuit pattern 120 from being separated from the molding member 140.

FIG. 5 is an illustrative view showing still another structure of the circuit pattern according to a preferred embodiment of the present invention.

Referring to FIG. 5, the circuit pattern 120 may have a hook part 123 formed on a side thereof. The hook part 123 may be formed in a hook structure which is upwardly protruded, on the side of the circuit pattern 120.

When the molding member 140 is formed on the circuit pattern 120, the molding member 140 may be filled up to the hook part 123 of the circuit pattern 120. Therefore, an adhering area between the circuit pattern 120 and the molding member 140 is increased by the hook part 123 of the circuit pattern 120.

The preferred embodiment of the present invention describes that the depression part 122, the protrusion part 121, and the hook part 123 are separately formed on the side of the circuit pattern 120 for each preferred embodiment of the present invention by way of an illustration in order to improve adhesion between the circuit pattern 120 and the molding member 140, but the present invention is not limited thereto. That is, two or more of the depression part 122, the protrusion part 121, and the hook part 123 may be complexly formed on one circuit pattern 120. In addition, the circuit pattern 120 may be patterned in any structure capable of increasing the adhering area between the circuit pattern 120 and the molding member 140, without being limited to the structure of the depression part 122, the protrusion part 121, and the hook part 123.

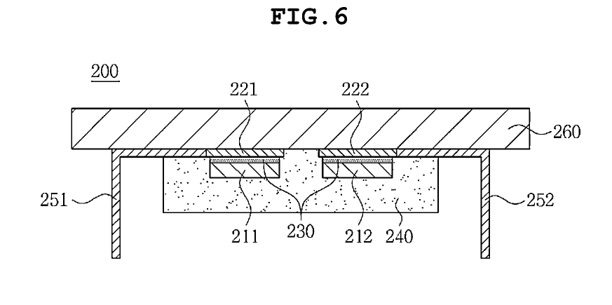

FIG. 6 is an illustrative view for a power semiconductor package according to another preferred embodiment of the present invention.

Referring to FIG. 6, a power semiconductor package 200 may include a first semiconductor device 211, a second semiconductor device 212, a first circuit pattern 221, a second circuit pattern 222, an attaching member 230, a molding member 240, a first lead frame 251, a second lead frame 252, and a heat radiating member 260.

The first semiconductor device 211 and the second semiconductor device 212 may include at least one of a power device and a control device. In the preferred embodiment of the present invention, the first semiconductor device 211 may be the power device. In addition, the second semiconductor elements 212 may be the control device. For example, the power device may include an insulated gate bipolar transistor (IGBT), a diode, or the like. In addition, the control device may include a control integrated circuit (IC), or the like.

However, a kind of first semiconductor device 211 and second semiconductor device 212 is not limited thereto.

The first circuit pattern 221 may be formed on one surface of the first semiconductor device 211. The first circuit pattern 221 may be electrically connected to the first semiconductor device 211. Alternatively, the first circuit pattern 221 may separately serve to transfer an electrical signal even though it is not electrically connected to the first semiconductor device 211.

The second circuit pattern 222 may be formed on one surface of the second semiconductor device 212. The second circuit pattern 222 may be electrically connected to the second semiconductor device 212. Alternatively, the second circuit pattern 222 may separately serve to transfer an electrical signal even though it is not electrically connected to the second semiconductor device 212.

In the preferred embodiment of the present invention, the first circuit pattern 221 and the second circuit pattern 222 may be formed of a conductive material. For example, the conductive material may be copper. However, the material of the first circuit pattern 221 and the second circuit pattern 222 is not limited to copper, and any conductive material used in a field of a circuit substrate may be used.

In addition, the first circuit pattern 221 and the second circuit pattern 222 may have the other surface formed so as to be buried in the molding member 240 and one surface formed so as to be exposed from the molding member 240, as shown.

In addition, in the preferred embodiment of the present invention, sides of the first circuit pattern 221 and the second circuit pattern 222 may be patterned. For example, the sides of the first circuit pattern 221 and the second circuit pattern 222 may be formed so that a portion thereof has a bent concave structure. Alternatively, the sides of the first circuit pattern 221 and the second circuit pattern 222 may be formed so that a portion thereof has a structure protruded from the sides. Alternatively, the first circuit pattern 221 and the second circuit pattern 222 may be formed so as to have a hook structure which is upwardly protruded, on the sides thereof. This structure may increase an adhering area between the first circuit pattern 221 and the second circuit pattern 222, and the molding member 240 to thereby improve adhesion therebetween.

The attaching member 230 may be formed between the first circuit pattern 221 and the first semiconductor device 211. In addition, the attaching member 230 may be formed between the second circuit pattern 222 and the second semiconductor device 212. The attaching member 230 formed as described above may improve adhesion between the first circuit pattern 221 and the first semiconductor device 211, and between the second circuit pattern 222 and the second semiconductor device 212. For example, the attaching member 230 may be formed of a solder. However, a material of the attaching member 230 is not limited to the solder. As the material of the attaching member 230, any material used in the field of the circuit substrate and capable of improving adhesion may be used.

The molding member 240 may be formed so as to bury the first semiconductor device 211, the second semiconductor device 212, the first circuit pattern 221, and the second circuit pattern 222. The molding member 240 may be formed so as to prevent configuration parts disposed therein from being damaged from an external environment. In this case, the molding member 240 may expose one surface of the first circuit pattern 221 and the second circuit pattern 222. That is, one surface of the molding member 240 and one surface of the first circuit pattern 221 and the second circuit pattern 222 may be collinearly disposed. For example, the molding member 240 may be formed of an epoxy molding compound (EMC).

The first lead frame 251 and the second lead frame 252 may be formed so as to electrically connect the power semiconductor package 200 to the outside. The first lead frame 251 may have one end connected to the first circuit pattern 221. In addition, the first lead frame 251 may have the other end formed so as to be protruded to the outside of the molding member 240. The second lead frame 252 may have one end connected to the second circuit pattern 222. In addition, the second lead frame 252 may have the other end formed so as to be protruded to the outside of the molding member 240. In this case, one surface of the first lead frame 251 and the second lead frame 252 may be formed so as to be exposed from the molding member 240. In the preferred embodiment of the present invention, the first lead frame 251 and the first circuit pattern 221 have been described as a separate configuration part. However, the first lead frame 251 and the first circuit pattern 222 may be separately formed to be adhered to each other, but may be integrally formed. The second lead frame 252 and the second circuit pattern 222 may also be separately formed, but may be integrally formed.

The heat radiating member 260 may be formed on the first circuit pattern 221 and the second circuit pattern 222. That is, the heat radiating member 260 may be directly adhered to one surface of the first circuit pattern 221 and the second circuit pattern 222 exposed from the molding member 240. In the preferred embodiment of the present invention, the heat radiating member 260 may be formed of a non-conductive material in order to insulate between the circuit patterns which are directly adhered to each other. In the preferred embodiment of the present invention, since the heat radiating member 260 may be formed of the non-conductive material, the insulation layer formed to insulate between the circuit patterns according to the prior art may be omitted.

Therefore, the power semiconductor package 200 according to the preferred embodiment of the present invention may omit the insulation layer due to the non-conductive heat radiating member 260. Therefore, the thermal resistance between the first circuit pattern 221 and the second circuit pattern 222, and the heat radiating member 260 is decreased, thereby improving the heat radiating effect.

According to the preferred embodiment of the present invention, the power semiconductor package may improve the heat radiating performance by directly contacting the circuit pattern having the semiconductor device mounted thereon and the heat radiating member.

Although the exemplary embodiment of the present invention has been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A power semiconductor package, comprising:
a semiconductor device;
a circuit pattern formed on the semiconductor device;
a molding member burying the semiconductor device and the circuit pattern and formed so as to expose one surface of the circuit pattern; and
a heat radiating member adhered to the circuit pattern exposed by the molding member and formed of a non-conductive material.

2. The power semiconductor package as set forth in claim 1, further comprising an attaching member formed between the semiconductor device and the circuit pattern to thereby attach to each other.

3. The power semiconductor package as set forth in claim 2, wherein the attaching member is formed of a solder.

4. The power semiconductor package as set forth in claim 1, wherein the circuit pattern is formed of a conductive material.

5. The power semiconductor package as set forth in claim 1, wherein the circuit pattern is formed of copper.

6. The power semiconductor package as set forth in claim 1, further comprising a lead frame having one end adhered to the circuit pattern and the other end protruded to the outside of the molding member.

7. The power semiconductor package as set forth in claim 6, wherein the lead frame is formed of a conductive material.

8. The power semiconductor package as set forth in claim 6, wherein the lead frame is formed of copper.

9. The power semiconductor package as set forth in claim 1, wherein the circuit pattern is formed so as to have a structure in which a portion of a side thereof is convexly protruded.

10. The power semiconductor package as set forth in claim 1, wherein the circuit pattern is formed so as to have a structure in which a portion of a side thereof is concavely depressed.

11. The power semiconductor package as set forth in claim 1, wherein the circuit pattern is formed so as to have a hook structure which is upwardly protruded, on a side thereof.

12. The power semiconductor package as set forth in claim 1, wherein a plurality of semiconductor devices are formed.

13. The power semiconductor package as set forth in claim 1, wherein the semiconductor device includes at least one of a power device and a control device.

14. The power semiconductor package as set forth in claim 12, wherein the circuit pattern is formed on each of the plurality of semiconductor devices.

15. The power semiconductor package as set forth in claim 14, wherein the heat radiating member is simultaneously adhered to the plurality of circuit patterns.
